(19) United States
(12) Patent Application Publication
(10) Pub. No.: US 2026/0271607 A1
(43) Pub. Date: Sep. 10, 2026

(54) METHOD FOR PRODUCING PEROVSKITE/SILICON TANDEM SOLAR CELLS

(71) Applicant: Helmholtz-Zentrum Berlin für Materialien und Energie Gmbh, Berlin (DE)

(72) Inventors: Johannes SUTTER, Berlin (DE); Philipp TOCKHORN, Berlin (DE); Christiane BECKER, Berlin (DE); Steve ALBRECHT, Werder Havel (DE)

(73) Assignee: Helmholtz-Zentrum Berlin für Materialien und Energie GmbH, Berlin (DE)

(21) Appl. No.: 18/844,997

(22) PCT Filed: Mar. 9, 2023
(86) PCT No.: PCT/DE2023/100180

§ 371 Date: May 14, 2026

(30) Foreign Application Priority Data
Mar. 9, 2022 (DE) 10 2022 105 533.7

(51) Int. Cl. H10K 71/12; H10F 10/172; H10F 71/00; H10F 71/10; H10K 30/40; H10K 71/00; H10K 71/40

(52) U.S. Cl. CPC H10K 71/12; H10F 71/103; H10F 71/128; H10F 71/134; H10K 71/40; H10K 71/821; H10F 10/172; H10K 30/40

(57) ABSTRACT

The invention relates to a method for manufacturing perovskite/silicon tandem solar cells, characterized by the creation of a front-side structure on a silicon wafer, wherein the structure is formed from inverted pyramids, with edge lengths of 1.5 μm to 6 μm for the base of the pyramids and 1 μm to 4 μm for the depth of the pyramids at a spacing of 1.5 μm to 6 μm, which allows for the structure-conformal deposition of a perovskite layer by spin coating.

The invention relates to a method for manufacturing perovskite/silicon tandem solar cells, such as those known from photovoltaic applications. The perovskite/silicon tandem solar cells may also be used without restriction for the formation of solar modules.

The improvement of solar cells is carried out in particular with a regard to improved efficiency, i.e., an improved ratio of the amount of light energy available for absorption to the amount of energy made available by the solar cell in the form of electrical current.

In addition to improving the efficiency of solar cells, another important aspect is their manufacturing, particularly with a view to making production as cost-effective as possible and suitable for industrial-scale manufacturing.

Perovskite/silicon tandem solar cells are candidates for high efficiency. Several physical properties of a solar cell contribute to its efficiency. In the review article, Paper 1, by S. Akhil et al. (Review on perovskite silicon tandem solar cells: Status and prospects of 2T, 3T, and 4T for real-world conditions, Materials & Design Vol. 211, 2021, 110138_1-36), various state-of-the-art findings regarding the efficiency and efficiency enhancement of perovskite/silicon tandem solar cells are presented, and aspects of their fabrication—such as the deposition of perovskite layers onto previously applied, structured layers—are discussed.

Among other factors, the proportion of light that is reflected within or at the solar cell—and is thus not available for absorption—is decisive for efficiency. Reflected light is available for absorption in the solar cell to a greatly reduced extent and, for the most part, not at all; consequently, it contributes very little, and in most cases not at all, to the efficiency of the solar cell.

There are several approaches to reducing the proportion of reflected light. One approach is to structure interfaces between layers of different materials in the layer stacks of the solar cells, in particular to reduce light reflection and also to provide so-called light-trapping structures. The structuring can be carried out in such a way that several successive layers in the stack each adopt the same structure as a layer applied first (at the very front or in a sequence of layer application, the one lying at the bottom), in that they are applied at every point of a given structure—i.e., in its valleys and peaks—with a consistently uniform (homogeneous) layer thickness. A structure-conforming layer replicates the structure of a structured layer lying beneath it in terms of the essential characteristics—namely the orders of magnitude of the height or depth of the structures and their geometric shape and dimensions—at the same location in the direction of the layer sequence as the underlying layer. In this context, one also speaks of structure-conforming application of layers or of layers applied in a structure-conforming manner to the layer directly beneath them.

The replication of the structures depends on the inevitable fluctuations in layer thickness that occur when applying a layer deposition process, caused by experimental conditions that cannot ultimately be fully controlled; consequently, the condition of structural conformity must be understood as a replication of the essential features of the structure while maintaining the functionality resulting from the structuring (e.g., reduction of reflections).

For perovskite/silicon tandem solar cells, the influence of structured layers on the reflection and light scattering properties of the solar cell is discussed, for example, in paper 2 by K. Jäger et al. (Prospects of light management in perovskite/silicon tandem solar cells, Nanophotonics; Vol. 10(8), 2021, pp. 1991-2000) and, for example, also in the paper 3 by F. Sahli et al. (Fully textured monolithic perovskite/silicon tandem solar cells with 25.2% power conversion efficiency, Nature Materials, Vol. 17, 2018, pp. 820-826) for a specific implementation of a perovskite/silicon tandem solar cell. The size and shape of the structures are decisive for the reflection and light scattering properties. A special form of structuring using so-called inverted pyramids is described in paper 4 by D. Shi et al. (Perovskite/c-Si tandem solar cell with inverted nanopyramids: realizing high efficiency by controllable light trapping, Scientific Reports, 2015, 5:16504, pp. 1-10), which has proven advantageous for so-called “light trapping.”

In paper 5 by Y. Hou et al. (Efficient tandem solar cells with solution-processed perovskite on textured crystalline silicon, Science, Vol. 367, 2020, pp. 1135-1140), the deposition of perovskite layers from solution onto a textured substrate to form perovskite/silicon tandem solar cells is examined in greater detail.

In paper 6 by B. Chen et al. (Blade-Coated Perovskites on Textured Silicon for 26%-Efficient Monolithic Perovskite/Silicon Tandem Solar Cells, Joule, Vol. 4, 2020, pp. 850-864), the deposition of a perovskite layer using the so-called “blade-coat” method—which involves coating from slot nozzles with a separately guided device (squeegee) for smoothing or homogenizing the layer thickness—in this case a device for providing a uniform N₂ flow, onto structured layers.

In paper 7 by M. Saliba et al. (Cesium-containing triple cation perovskite solar cells: improved stability, reproducibility and high efficiency, Energy & Environmental Science, Vol. 9, 2016, pp. 1989-1997), the application of perovskite layers by spin coating is described.

In addition to the “blade-coat” method and solution deposition, the so-called “spin coating” (in German: Aufschleudern, Rotationsbeschichtung) should also be mentioned for the formation of perovskite layers. In the context of the present invention, “spin coating” refers to a single-step process in which the material required to form a perovskite layer is not applied sequentially as separate components of the perovskite composition, but rather in a single step as the material itself.

Although spin coating can be used to produce high-quality layers that contribute to highly efficient solar cells, as described, for example, in paper 2, according to the prior art, this type of coating cannot be used to produce structurally conformal perovskite layers, as described, for example, in paper 3.

In paper 8 by B. W. Schneider et al. (Pyramidal surface textures for light trapping and antireflection in perovskite-on-silicon tandem solar cells, Optics Express, Vol. 22, 2014, pp. A1422-A1430), the improvement in efficiency through enhanced light management is discussed, and it is theoretically demonstrated that the conformal deposition of perovskite layers onto patterned silicon layers is promising. The silicon patterning under consideration consists of inverted pyramids.

The properties of a silicon layer structured with inverted pyramids and coated with gold for infrared absorption are further demonstrated in paper 9 by J. Hu et al. (Efficient infrared sunlight absorbers based on gold-covered, inverted silicon pyramid arrays, Materials Advances, Vol. 3, 2022, pp. 2364-2372), which also describes a method for fabricating the inverted pyramids using nano-embossing lithography. U.S. Pat. No. 4,528,260 A discloses a photolithographic method for fabricating inverted pyramids in silicon.

Finally, EP 3 893 285 A1 should be mentioned, which discloses a method for manufacturing silicon/perovskite tandem solar cells. The perovskite layers are formed in particular from laminated, i.e., stacked, perovskites of different compositions. The tandem solar cell as a whole is, in particular, monolithically constructed and may be built on a silicon layer textured with irregular pyramids, onto which the remaining functional layers of the tandem solar cell are applied layer by layer. The figures suggest a structure-conformal deposition of the layers.

The objective of the invention is to provide a method for manufacturing perovskite/silicon tandem solar cells that features a structure optimized for reduced reflection and, at the same time, allows for the deposition of perovskite layers that results in high efficiency of the manufactured solar cells.

The objective is solved by the features of Claim 1.

Surprisingly, a protocol for a method of manufacturing perovskite/silicon tandem solar cells was discovered at HZB; this method incorporates a patterning optimized for reduced reflection while also enabling the conformal deposition of a perovskite layer via spin coating. The patterning is characterized by a defined area of inverted pyramids, which are created by nano-embossing lithography or foltolithography and dry and wet chemical etching, and which enable the spin coating of a perovskite layer conforming to the structure.

Perovskite, as defined by the invention, refers to all compounds that can be described by the molecular formula ABX3 and that crystallize in the crystal structure of the mineral perovskite, comprising, as component A, for example, methylammonium (MA), cesium (Cs), and/or formamidinium (FA), while component B is frequently provided by lead (Pb). X is, for example, iodine (I), bromine (Br), and/or chlorine (Cl) or a mixture of these elements. Preferably, Cs_{0.05}(FA_{0.79}MA_{0.21})_{0.95}Pb(I_{0.79}Br_{0.21})₃ or similar compositions are used.

The method according to the invention for manufacturing perovskite/silicon tandem solar cells involves first providing a silicon wafer that is (100)-oriented and monocrystalline. Such silicon wafers for the manufacture of solar cells are well known to those skilled in the art. The silicon wafer forms the absorber of the rear subcell (silicon subcell) in the tandem solar cell.

Additional layers, particularly for completing the solar cell—such as to form a p-n junction with the silicon absorber via a corresponding doped additional silicon layer—are to be provided as needed in subsequent steps of the process.

In a further step, the first side of the silicon wafer—which is thereby defined as the front side—is first patterned using a lithography process, such as nanoimprint lithography or photolithography, followed by a dry and wet chemical etching step. The second side of the silicon wafer, opposite this first side, is thus to be referred to as the back side.

To this end, a silicon dioxide layer with a thickness in the range of 200 nm to 500 nm is first applied to the first side of the silicon wafer. This is advantageously carried out by plasma-enhanced chemical vapor deposition (PECVD). Other methods for applying the silicon dioxide layer, such as physical vapor deposition (PVD) or high-temperature oxidation, are known to those skilled in the art and are equally applicable in the method of the invention.

A layer of photoresist is then applied to the silicon dioxide layer, e.g., by spin coating or other methods. The photoresist advantageously consists of an organic material and is applied with a layer thickness in the range of 100 nm to 500 nm.

In a further step according to the invention, a regular structure of cylindrical holes is introduced into the photoresist via nanoimprint lithography or photolithography to form a mask, wherein, according to the invention, the holes have a diameter in the range of 1 μm to 5 μm and the holes are spaced apart from one another in the range of 1.5 μm to 6 μm apart, and in the stamp, the corresponding cylinders intended for creating the holes (with diameters ranging from 1 μm to 5 μm and spaced 1.5 μm to 6 μm apart) have a height ranging from 100 nm to 500 nm. The patterning is performed using the stamp, which is pressed into the photoresist, after which the photoresist is cured by irradiation with UV light. The fabrication of a stamp and further information on the process of nanoimprint lithography can be found, for example, in paper 10 by L. J. Guo (Nanoimprint Lithography: Methods and Material Requirements, Advanced Materials, Vol.: 19(4), 2007, pp. 495-513).

Using the photoresist mask, the structure of the mask is subsequently transferred into the silicon dioxide layer via directional (anisotropic), reactive ion etching. The etching time must be determined experimentally so that etching proceeds only until the silicon wafer is reached. For ion etching, reactive ion etching using a plasma, e.g., of argon and CHF₃ or SF₆, is advantageously employed. A mask is formed in the silicon dioxide layer that corresponds to the mask that was introduced into the photoresist. This silicon dioxide mask is sufficiently stable against etching with potassium hydroxide or other etching agents. The photoresist is typically removed using an oxygen plasma or through wet chemical etching.

In the subsequent step, wet chemical etching is performed through the mask, preferably using, for example, a potassium hydroxide or sodium hydroxide solution or tetramethylammonium hydroxide. Etching continues until inverted pyramids are formed, i.e., until the side faces of the pyramids meet at a single point. The etching time determined by these conditions must be determined experimentally for each specific application by examining the etching results, e.g., via scanning electron microscope images, and adjusting the etching time accordingly. In this wet chemical etching step, the entire silicon wafer is subjected to etching. As a result, etching also occurs on the rear surface of the silicon wafer, the second side, which textures the surface of this second side irregularly through the random formation of pyramids.

The inverted pyramids thus created on the surface of the front side of the silicon wafer have the following dimensions: The base of the pyramids has edge dimensions in a range of 1.5 μm to 6 μm, and the depth is in a range of 1 μm to 4 μm, with a spacing of 1.5 μm to 6 μm. An inverted pyramid as defined by the invention is the reverse spatial shape (the negative) of a pyramid as a depression in a layer (here the silicon layer), wherein the base of the inverted pyramid is defined by the opening in the layer. It should be noted that the holes, which are transferred by the stamp into the photoresist and, through directional etching, also into the silicon dioxide layer, have a smaller diameter than the edge lengths of the pyramids formed by dry or wet chemical etching.

Functional layers required for the final completion of the tandem solar cell—in this case, specifically the silicon subcell—are first applied to the second side of the silicon wafer. These include at least one layer for forming a corresponding p-n junction with the silicon wafer and a contact layer. Functional layers—specifically at least one passivation layer, one recombination layer, and one hole-conductor layer—are then applied conformally to the first side of the silicon wafer, which is structured with the inverted pyramids. Additional layers are possible. The methods for applying the layers are known to those skilled in the art and can be found in the relevant literature.

Subsequently, a perovskite layer is applied conformally by spin-coating a perovskite solution, wherein the applied perovskite layer has a thickness in the range of 300 nm to 700 nm. The perovskite layer is then completed by salting out the applied perovskite solution and subsequent annealing.

To finally complete the perovskite/silicon tandem solar cell, at least the following functional layers—an electron transport layer, a buffer layer, a transparent conductive oxide, a metal contact, and an antireflective layer—are applied to the perovskite layer in a structure-conformal manner. Additional layers are possible. The methods for applying the layers are known to those skilled in the art and can be found in the relevant literature.

The invention relates to the manufacture of perovskite/silicon tandem solar cells according to the method described above, having the following features. A silicon wafer serving as the absorber of the silicon subcell is structured with regularly arranged inverted pyramids having dimensions of 1.5 μm to 6 μm for the base of the pyramids and 1 μm to 4 μm for the depth of the pyramids, with a spacing of 1.5 μm to 6 μm, and wherein all overlying layers in the tandem solar cell, following the silicon absorber as the lower layer, are formed in a manner conforming to the structure in the silicon layer, in particular at least one perovskite layer as an absorber in the perovskite subcell.

Such a perovskite/silicon tandem solar cell has the advantage that it can be manufactured using the method of the invention and thus exhibits a patterning suitable for reducing reflections, while at the same time the perovskite layer in the tandem solar cell can be deposited by spin coating, which results in improved efficiency. In the perovskite/silicon tandem solar cell manufactured according to the method of the invention, the perovskite layer is textured on both sides in a manner conforming to the structure.

The invention is explained in more detail in the following example of implementation and with reference to two figures.

In this context, it is shown in

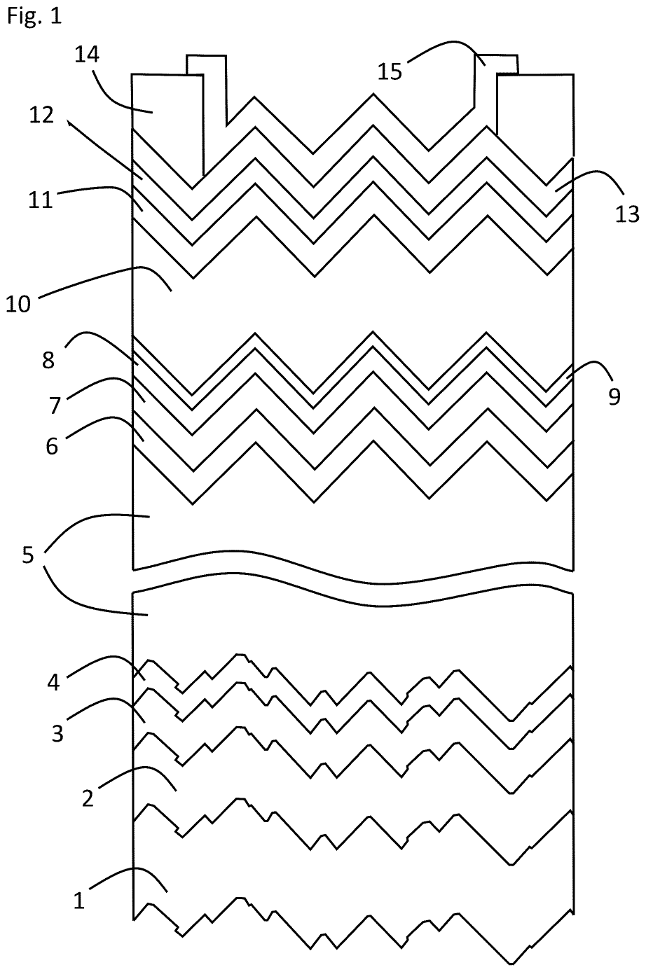

FIG. 1: a schematic representation of a perovskite/silicon tandem solar cell manufactured using the method of the invention.

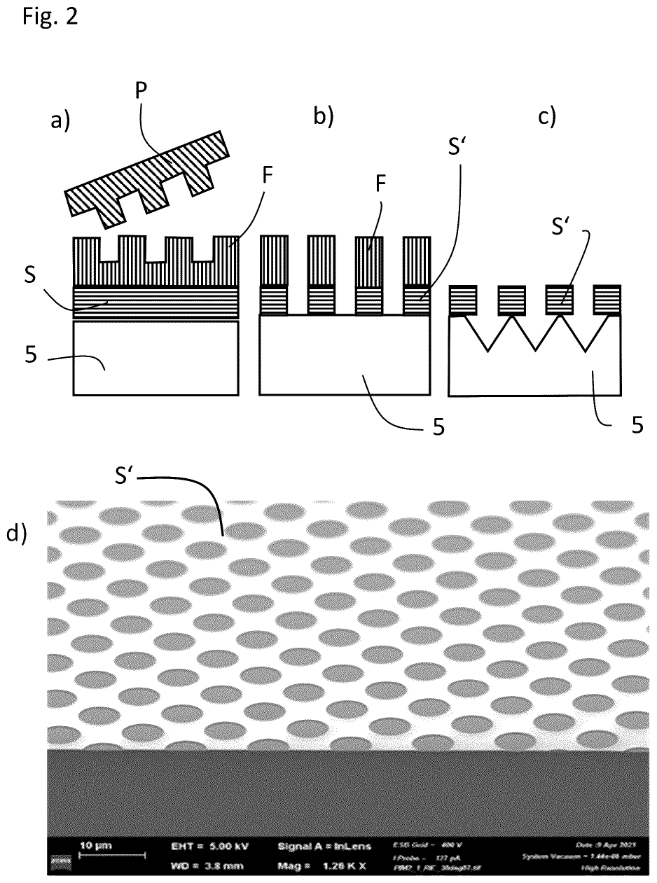

FIG. 2: a schematic representation of steps (a)-(c) of the nanoimprint-lithography process used according to the invention (state of the art) and (d) SEM image of a silicon dioxide layer structured in this manner for the production of the inverted pyramids according to the invention in a silicon wafer.

FIG. 1 shows the layers of a perovskite/silicon tandem solar cell produced in the embodiment according to the method of the invention. The layers are identified as follows, from bottom to top:

Functional layers:
1: Back reflector (silver)
2: Doped SnO (stannic oxide)
3: (p) a-Si:H
4: (i) a-Si:H

Absorber of the silicon subcell:
5: Silicon wafer (shown as a dashed line)

Functional layers:
6: (i) a-Si:H
7: (n) nc-Si:H
8: Doped SnO (stannic oxide)
9: Hole-conductor layer made of Me-4PACz

Absorber of the perovskite subcell:
10: Perovskite (Cs_{0.05}(FA_{0.79}MA_{0.21})_{0.95}Pb(I_{0.79}Br_{0.21})₃)

Functional layers:
11: C₆₀
12: SnO₂ (tin(IV) oxide)
13: IZO (indium—zinc oxide)
14: Silver ring (see also below)
15: LiF (lithium fluoride)

The layer thicknesses are not shown to scale and are for orientation purposes only. The numbering of the layers is for reference only and corresponds to the layer sequence in the finished tandem solar cell, but does not refer to the sequence of layer deposition. The silicon wafer 5, acting as the absorber, is structured with inverted pyramids on a first side (shown at the top in the figure) in accordance with the method of the invention. The silicon wafer 5 is to be considered the bottom layer for layers 6-15, particularly with regard to the sequence of layer deposition. However, the silicon wafer 5 is also to be regarded as the bottom layer for the sequence of layer deposition—though not for the layer sequence in the final tandem solar cell—for the rear layers 1-4. The silicon wafer 5 is patterned on both sides by the wet chemical etching step of the method according to the invention. On the first side, which is the top side in the figure, it is patterned using the method according to the invention, and on the lower second side, it is provided with a random pyramidal structure by the wet chemical etching step.

Both the lower layers (1-4) and the upper layers (6-15) are applied conformally to the respective surfaces of the silicon wafer 5.

In the embodiment of the method according to the invention for manufacturing perovskite/silicon tandem solar cells, a monocrystalline silicon wafer with (100) orientation (the {100} crystal planes of silicon coincide with the surface of the wafer) is first provided. The silicon wafer 5 is provided on a first side with a silicon dioxide layer S (not shown in FIG. 1, as it is removed again during the process) via PECVD with a layer thickness of 260 nm. A commercially available organic photoresist, mr-NIL210 from micro resist technology GmbH F, is applied to this with a layer thickness of 500 nm (not shown in FIG. 1, as it is removed again during the process). A hole structure is introduced into the photoresist F using nanoimprint lithography (FIG. 2a). This is done using a stamp P made of polydimethylsiloxane (PDMS), which is formed by transfer from a master structure. The stamp P is pressed into the UV-curable photoresist F, after which the photoresist F is cured with UV light. After removing the PDMS stamp S, the structure reproduced in the photoresist F is etched anisotropically into the silicon oxide layer S previously applied to the silicon wafer 5 using reactive ion etching with a plasma of argon and CHF₃, thereby transferring it (FIG. 2b)). The photoresist is removed using an oxygen plasma. The resulting silicon oxide mask S [symbol] is sufficiently stable against etching with potassium hydroxide and exhibits a periodic hole structure introduced by the stamp P, with holes having a diameter of 2.5 μm and a spacing of 4 μm (FIG. 2 d)). The holes in the patterned silicon dioxide layer S [symbol] extend down to the silicon wafer and thus have a depth corresponding to the thickness of the silicon dioxide layer. Potassium hydroxide etching creates inverted pyramids in the silicon wafer 5 at the locations defined by the holes in the silicon dioxide layer S [symbol] (FIG. 2c), the periodicity of which is determined by the mask of the silicon dioxide layer S [symbol] The pyramids are formed due to the highly selective etching preference of the (100) planes of the monocrystalline silicon 1 during wet chemical etching, performed in the embodiment with potassium hydroxide.

The pyramid flanks always form the same angle of 54.74°, whereby the depth of the pyramid structures is determined by the distance to the next pyramid. The pyramids in the embodiment have the following dimensions: 4 μm for the edges of the pyramid bases and a depth of 2.8 μm for the pyramids at a spacing of 4 μm (the pyramids are in contact).

The silicon dioxide etch mask is removed after wet chemical etching with potassium hydroxide using a buffered oxide etchant (BOE). After cleaning using a standard RCA cleaning process, as is also used in microelectronics, the double-sided textured silicon wafer is further processed into a perovskite/silicon tandem solar cell.

On the back side, to complete the tandem solar cell and in particular the silicon subcell, the following layers are now first deposited: (i) a-Si:H₄, (p) a-Si:H₃, doped tin(II) oxide SnO₂, and a back-side reflector made of silver 1 are first applied to the second side of the silicon wafer using standard methods.

In the embodiment, the first, front side of the silicon wafer 5, which is structured with inverted pyramids, is first passivated by hydrogenated intrinsic amorphous silicon (via PECVD) ((i) a-Si:H, 6), and then the following functional layers are deposited conformally thereon: (n) nc-SiOₓ:H (hydrogenated n-doped nanocrystalline silicon oxide, deposited by PECVD) 7, a recombination layer of transparent, conductive oxide (here, doped tin oxide deposited by sputtering) 8, and subsequently, as a selective hole contact, a layer of Me-4PACz ([4-(3,6-dimethyl-9H-carbazol-9-yl)butyl]phosphonic acid) 9 deposited by spin coating.

Subsequently, a perovskite layer 10 is spin-coated at 3500 rpm for 40 s. 5 s before the end of the program, 500 μL of ethyl acetate is poured onto the rotating substrate as an anti-solvent for salt leaching. A “triple cation” perovskite Cs_{0.05}(FA_{0.79}MA_{0.21})_{0.95}Pb(I_{0.79}Br_{0.21})₃ is used as the perovskite layer. The spin-coated layer is then dried at 100° C. for 30 min. The resulting conformally coated perovskite layer completely covers the underlying texture (without interruption).

The perovskite/silicon tandem solar cell is fabricated by the conformal deposition of the functional layers: an electron transport layer of C₆₀ ([60]fullerene) 11, a buffer layer of tin(IV) oxide SnO₂ 12, a transparent conductive oxide layer of indium zinc oxide 13, a contact ring consisting of silver 14, and an antireflective lithium fluoride layer LiF 15 using standard methods.

1. A method for manufacturing perovskite/silicon tandem solar cells, comprising at least the following steps:
providing a (100)-oriented, monocrystalline silicon wafer (5),
depositing a silicon dioxide layer (S) on a first side of the silicon wafer (5),
applying a layer of photoresist (F) to the silicon dioxide layer (S);
introducing a regular structure into the photoresist (F) by nano-embossing lithography using a stamp (P) to form a mask,
Directed, reactive ion etching of the silicon dioxide layer (S) through the mask formed by the layer of photoresist (F) to transfer the structure of the mask into the silicon dioxide layer (S);
Subsequently, wet chemical etching of the silicon wafer;
Deposition of back-side functional layers on a second side of the silicon wafer (5) and deposition of at least the following functional layers—passivation layer, recombination layer, and hole-conductor layer (9)—on the first side of the silicon wafer;
Subsequently, applying a perovskite layer (10) conforming to the structure by spin-coating a perovskite solution onto the hole-conductor layer (9)
Salt-out of the perovskite solution followed by annealing, wherein the applied perovskite layer (10) has a layer thickness in the range of 300 nm to 700 nm;
Deposition of front-side functional layers to complete the perovskite/silicon tandem solar cell,
wherein
the regular structure is formed from cylindrical holes, wherein the holes have a diameter in the range of 1 μm to 5 μm and the holes are spaced apart from one another in the range of 1.5 μm to 6 μm.
